(19) United States
(12) Patent Application Publication
(10) Pub. No.: US 2014/0026815 A1
(43) Pub. Date: Jan. 30, 2014

(54) Separating Device and Method for Producing A Crucible For Said Separating Device

(71) Applicant: Johan Mathiasson, Uppsala (SE)

(72) Inventor: Johan Mathiasson, Uppsala (SE)

(73) Assignee: SOLIBRO GMBH, Bitterfeld-Wolfen (DE)

(21) Appl. No.: 13/982,985

(22) PCT Filed: Jan. 31, 2012
(86) PCT No.: PCT/DE2012/100020

§ 371 Date: Oct. 21, 2013

(30) Foreign Application Priority Data
Feb. 4, 2011 (DE) 10 2011 000 502.1

(51) Int. Cl. H01L 31/18; C23C 16/448; C23C 14/24

(52) U.S. Cl. CPC H01L 31/18; C23C 14/243; C23C 16/448
USPC 118/726; 205/122; 29/527.4

(57) ABSTRACT

The invention refers to a deposition apparatus comprising a crucible (1) and heating means (2) arranged for heating evaporation material (3) inside the crucible (1), whereby the crucible (1) comprises a metallic body (11) and a protection layer (13) comprising titanium oxide (TiₓO_{y}), which is covering at least a part of the inside surface (12) of the metallic body (11). Furthermore, the invention refers to a method for producing a crucible for such a deposition apparatus.

The invention relates to a deposition apparatus for depositing thin layers and to a method for producing a crucible for such a deposition apparatus.

Such a deposition apparatus may for example be utilized for depositing some or all layers of a thin layer solar cell onto a substrate. In particular copper, indium, gallium, and selenium films may be deposited onto a substrate to produce so called CIGS solar cells. For this purpose, the material to be deposited is placed in a crucible of the deposition apparatus and heated, while the substrate is positioned opposite an opening of the crucible. The heating of the material inside the crucible leads to the material being evaporated and leaving the crucible through the opening to cover the substrate.

As the material is heated inside the crucible, it may react with the material of the crucible itself, leading to corrosion of the crucible surface and a subsequent degeneration of the crucible with time. There are examples of crucibles made of titanium being used for evaporating materials. Such crucibles are for example disclosed in US2008173241A and US2006096542A. The problem of corrosion and consecutive degeneration of the efficiency of the crucible is particularly acute when evaporating selenium inside a titanium crucible. Such crucibles need to be replaced frequently, leading to high production costs and frequent downtime.

In some instances, crucibles made of titanium oxide have been used in deposition devices. One such case is the use of crucibles made of titanium oxide, tantalum oxide, zirconium oxide, or silicon oxide, as described in US2009061079A, for the manufacture of Lithium ion batteries. The use of such inert materials for the entire crucible alleviates the problem of a reaction with the deposition material. However, such ceramic crucible materials are very brittle and have to be handled with much care. They may also easily break when not handled properly or when exposed to sudden temperature changes, thus again leading to downtime.

It is an object of the present invention to suggest a reliable device for deposition of a range of materials, which provides for lower maintenance costs, leading to a robust effusion process with longer up times.

The object is achieved by this invention by providing a deposition apparatus with the features of claim 1 and a method for producing a crucible for such an apparatus according to the features of claim 8. Advantageous embodiments of the invention are subject of the sub-claims.

The invention is based on the combined advantages of a crucible body made of metal and a protection layer to separate that metal material from deposition material, thus protecting the crucible from corrosion. Having a metal body, the crucible provides the advantage of being less sensitive to temperature changes. Furthermore, the metal body of the crucible may be cheaper to produce than a crucible made entirely of a ceramic material.

As only the inside of the crucible may come into contact with the deposition material, it can be sufficient to only cover part or all of the inside surface of the crucible body with the titanium oxide (TiₓO_{y}) protection layer. In other embodiments, however, it might be advantageous to cover the entire crucible body with the protection layer, which may even be easier to achieve.

Besides the crucible, the deposition apparatus requires heating means for heating the deposition material, which may for example be selenium, placed inside the crucible to the required temperature for deposition. Although such heating may be performed through direct heating of the deposition material, it may be advantageous to first heat the crucible such that the deposition material is heated indirectly as a result. The heating means may thus comprise one or multiple resistive heaters arranged in contact or near the crucible. Other heating means for directly or indirectly heating the deposition/evaporation material may include inductive heating means, laser heating means, ion heating means, or other suitable devices.

The step of covering the crucible body with the protection layer may be performed just before putting a new crucible inside a deposition apparatus in use.

The protection layer may be produced on the surface of the crucible body by way of a deposition method such as physical or chemical deposition, for example by electroplating the titanium oxide onto the metal surface. However, in an advantageous embodiment, the titanium oxide (TiₓO_{y}) of the protection layer is an induced oxide layer. In this case, the titanium oxide protection layer is produced by oxidizing said part of the inside surface of the crucible body. For this to work, at least this surface part of the crucible has to be made of a titanium based alloy of a certain thickness. In other words, the crucible body may be made of a layered metal structure with the top layer or a part of the top layer comprising a titanium based alloy.

If the titanium oxide of the protection layer is an induced oxide layer, it may be produced by heating the crucible body in an oxygen atmosphere or in an oxygen-rich atmosphere, for example inside a furnace.

In an advantageous embodiment, the body of the crucible is made of a titanium based alloy. It may even be made entirely of a titanium based alloy, which is later either covered by titanium oxide, or which surface may be oxidized in order to build the protective layer of titanium oxide.

A titanium based alloy in the present sense may be any metallic alloy the main constituent element of which is titanium. In other words, titanium is the element with the highest proportion in a titanium based alloy. The material should contain enough titanium to form a covering titanium oxide. Preferably, the titanium content of such a titanium based alloy is at least 50 weight percent (wt %). However, advantageously, the titanium proportion is much higher, such as above 60 wt %, above 70 wt %, above 80 wt %, above 90 wt %, or above 95 wt %. A titanium based alloy in the sense of the invention may also be a pure titanium metal, or a titanium metal that has contaminants or impurities of a different material.

In preferred embodiments, the titanium based alloy of the crucible body comprises palladium. Alternatively or additionally, other elements may be added to the titanium based alloy to improve its physical or chemical characteristics.

In advantageous embodiments, the body of the crucible is made of sheet metal. The sheet metal may be produced by way of a rolling process. The crucible body may be made out of two or more pieces joined together.

The protection layer covering at least a part of the inside surface of the crucible should preferably have a thickness of at least 50 nm, at least 100 nm, at least 150 nm, at least 200 nm, at least 300 nm, or at least 500 nm. It is of advantage for the protection layer to have a certain minimum thickness in order to protect the metal of the crucible body. A thickness of a few nanometers or less might be too low for this purpose. On the other hand, if the protection layer is too thick, it might peel off due to the brittle structure of the titanium oxide. The surface of the crucible would then be exposed and prone to react with the evaporation material.

In a preferred embodiment of the deposition apparatus, means for holding a solar cell substrate are provided for deposition of evaporation material placed inside the crucible onto a surface of the solar cell substrate. Such a deposition apparatus may for example be designed for depositing one or some of the layers for the manufacture of thin film solar cells, preferably of CIGS solar cells. In particular, the deposition apparatus may be designed to coat a substrate with selenium. Thus, the holding means would advantageously allow the placement of a substantially rectangular glass panel adjacent to the crucible opening.

The crucible body may be manufactured by any suitable method before being covered fully or partially with the protection layer. One preferred method that can be employed for the manufacture of the metallic material for the body of the crucible is a rolling process, namely either a hot or a cold rolling of the metal. The metal sheet produced this way may then be shaped into the crucible body. Alternatively, all or part of the crucible body may be obtained through casting from a melted metal or through machining out of a metal piece.

Some examples of embodiments of the invention will be explained in more detail in the following description with reference to the accompanying schematic drawings, wherein:

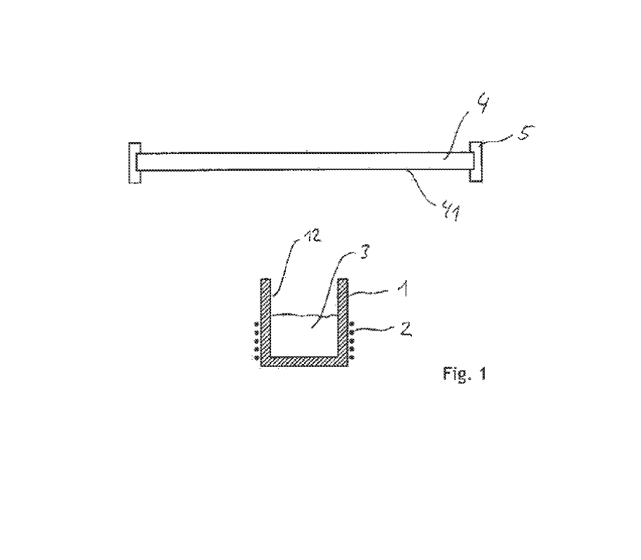

FIG. 1 shows a setup for depositing a material from a crucible onto a substrate;

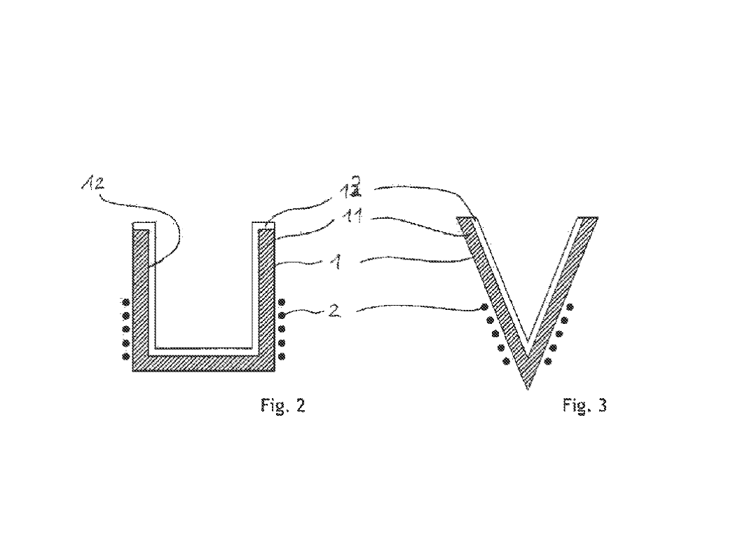

FIGS. 2 and 3 show different embodiments of a crucible of a deposition apparatus according to the invention; and

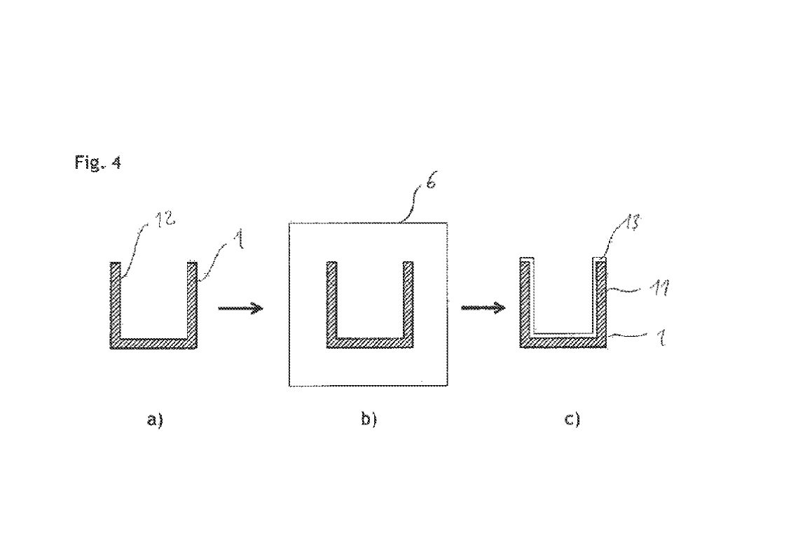

FIG. 4a) to c) illustrate a method for producing a crucible according to one embodiment of the invention.

FIG. 1 shows a schematic view of a deposition setup comprising a substrate 4 that is held by substrate holders 5. A surface 41 of the substrate 4 is facing a crucible 1, which is filled with a deposition material 3. Heating means 2 are arranged around the crucible 1, which can heat the crucible 1 and consecutively the deposition material 3, which thus evaporates and condenses onto the substrate surface 41 to be coated with the deposition material 3. The rest of the deposition apparatus comprising the crucible 1 and the substrate holders 5 is not shown in FIG. 1, for example a vacuum chamber in which the crucible 1 is placed.

If the crucible 1 is made entirely out of metal, there is the possibility for the deposition material (evaporation material) 3 to react with the inside surface 12 of the crucible 2 when heated to a sufficient degree. However, the crucible 1 according to the invention has its inside surface 12 at least partly covered by a protection layer 13. Advantageous embodiments of such a crucible 1 are shown in FIGS. 2 and 3.

While the crucible 1 shown in FIG. 2 has cylindrical side walls and may have a square, a rectangular, a circular or any other appropriate shape, the crucible 1 shown in FIG. 3 has a conical shape. In both cases, the crucible 1 comprises a crucible body 11 and a protection layer 13, which covers at least part of the inside surface 12. In the embodiments shown in FIGS. 2 and 3, the entire inside surface 12 of the crucible 1 is covered by the protection layer 13. In other preferred embodiments, the crucible body 11 may be covered entirely by the protection layer 13.

The crucibles shown in FIGS. 2 and 3 are each provided with heating means 2 for heating the evaporation material (not shown in FIGS. 2 and 3) to facilitate the evaporation thereof onto the substrate 4. While here they are shown schematically as resistive heaters, the heating means 2 may comprise any kind of heating devices for transferring energy onto the evaporation material 3 inside the crucible 1 in order to allow for particles of the evaporation material 3 to escape the crucible 1 and be deposited onto the substrate surface 41. Examples for such devices include inductive heating means, laser heating means, ion heating means, and the like.

FIGS. 4a), 4b), and 4c) illustrate schematically a method for the manufacture of a crucible 1 with a protection layer 12 according to a preferred embodiment. For this procedure, a crucible 1 with a crucible body 11 made of a metal is provided, as shown in FIG. 4a). The crucible body 11 may for example be made of sheet metal that was obtained through a rolling process. The crucible body 12 used for this process is preferably made of a titanium based alloy.

In a later step, as shown in FIG. 4b), the crucible body 12 is placed inside a furnace 6 to be heated. By heating the crucible in an oxygen atmosphere, the entire surface or, in case of a limited exposure to oxygen, part of the surface of the crucible is oxidized to form the protection layer, shown schematically in FIG. 4c). The protection layer may in addition be made stronger by way of a deposition method such as physical or chemical deposition. Such methods my alternatively be utilized to produce the protection layer in its entirety.

### REFERENCE NUMERALS

1 crucible

11 substrate body

12 inside surface

2 heating means

3 evaporation material (deposition material)

4 substrate

41 substrate surface

5 substrate holder

6 furnace

1. Deposition apparatus comprising a crucible (1) and heating means (2) arranged for heating evaporation material (3) inside the crucible (1), whereby the crucible (1) comprises a metallic body (11) and a protection layer (13) having a thickness of at least 50 nm and comprising titanium oxide (TiₓO_{y}), which is covering at least a part of the inside surface (12) of the metallic body (11), whereby the body (11) of the crucible (1) is made of titanium or a titanium based alloy.

2. Deposition apparatus according to claim 1, characterized by that the titanium oxide (TiₓO_{y}) of the protection layer (12) is an induced oxide layer.

3. (canceled)

4. Deposition apparatus according to claim 1, characterized by that the titanium based alloy comprises Palladium.

5. Deposition apparatus according to claim 1, characterized by that the body of the crucible is made of sheet metal.

6. Deposition apparatus according to claim 1, characterized by that the protection layer has a thickness of at least 50 nm, at least 100 nm, at least 150 nm, at least 200 nm, at least 300 nm, or at least 500 nm.

7. Deposition apparatus according to claim 1, characterized by means for holding a solar cell substrate for deposition of evaporation material (3) placed inside the crucible (1) onto a surface of the solar cell substrate.

8. Method for producing a crucible (1) for a deposition apparatus comprising the steps of providing a crucible body (11) made of a metallic material and covering at least a part of the inside surface (12) of the metallic body (11) by a protection layer (13) having a thickness of at least 50 nm and comprising titanium oxide (TiₓO_{y}), whereby the body (11) of the crucible (1) is made of titanium or a titanium based alloy.

9. Method according to claim 8, characterized by that the Titanium oxide protection layer is produced by oxidizing said part of the inside surface of the crucible body.

10. Method according to claim 8, characterized by that the metallic material for the body of the crucible is produced in a rolling process.
